(19) United States
(12) Patent Application Publication
(10) Pub. No.: US 2026/0096097 A1
(43) Pub. Date: Apr. 2, 2026

(54) SEMICONDUCTOR DEVICES AND FABRICATION METHODS THEREOF

(71) Applicant: Yangtze Memory Technologies Co., Ltd., Wuhan (CN)

(72) Inventors: Kun ZHANG, Wuhan (CN); Linchun WU, Wuhan (CN); Yuhui HAN, Wuhan (CN); Tingting GAO, Wuhan (CN); Wenxi ZHOU, Wuhan (CN); Zhiliang XIA, Wuhan (CN); Zongliang HUO, Wuhan (CN)

(21) Appl. No.: 18/932,053

(22) Filed: Oct. 30, 2024

(30) Foreign Application Priority Data
Sep. 29, 2024 (CN) 202411375209.6

(51) Int. Cl. H10B 43/27

(52) U.S. Cl. CPC H10B 43/27

(57) ABSTRACT

The present disclosure relates to semiconductor devices and fabrication methods thereof. The semiconductor device includes a first stack and a second stack. The first stack includes a first and second deck of conductive and insulating layers alternating with each other along the first direction. The second stack includes a first and second deck of dielectric and insulating alternating with each other along the first direction. The semiconductor device further includes a first connecting layer connecting a first conductive layer of the first deck of the first stack with a first dielectric layer of the first deck of the second stack along a second direction, and a second connecting layer connecting a second conductive layer of the second deck of the first stack with a second dielectric layer of the second deck of the second stack along the second direction.

### CROSS-REFERENCE TO RELATED APPLICATIONS

This application claims priority to Chinese Patent Application No. 202411375209.6, filed on Sep. 29, 2024, which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems, and techniques for managing contact structures in semiconductor devices.

One aspect of the present disclosure features a semiconductor device. The semiconductor device includes: a first stack of conductive layers and insulating layers alternating with each other along a first direction, where the first stack includes a first deck of conductive layers and insulating layers and a second deck of conductive layers and insulating layers; a second stack of dielectric layers and insulating layers alternating with each other along the first direction, where the second stack includes a first deck of dielectric layers and insulating layers and a second deck of dielectric layers and insulating layers; a first connecting layer connecting a first conductive layer of the first deck of the first stack with a first dielectric layer of the first deck of the second stack along a second direction perpendicular to the first direction; a second connecting layer connecting a second conductive layer of the second deck of the first stack with a second dielectric layer of the second deck of the second stack along the second direction; and an isolating structure extending through the first deck of the second stack along the first direction, where the isolating structure extends through the first connecting layer and the second connecting layer along the first direction, and the isolating structure includes a dielectric layer.

In some implementations, the semiconductor device further includes: a first contact structure extending through the first deck of the second stack along the first direction, where the first contact structure extends through and is connected with the first connecting layer; and a second contact structure extending through the first deck and the second deck of the second stack along the first direction, where the second contact structure extends through the first connecting layer and the second connecting layer and is connected with the second connecting layer, and the second contact structure is isolated from the first connecting layer by a dielectric spacer.

In some implementations, the first stack further includes a third deck of conductive layers and insulating layers; a third connecting layer connects a third conductive layer of the third deck of the first stack with a third dielectric layer of the third deck of the second stack along the second direction; a third contact structure extends through the first deck, the second deck, and the third deck of the second stack along the first direction, where the third contact structure extends through the first connecting layer, the second connecting layer, and the third connecting layer, the third contact structure is connected with the third connecting layer, and the third contact structure is isolated from the first connecting layer and the second connecting layer by dielectric spacers; and the isolating structure extends through the first deck and the second deck of the second stack along the first direction and extends through at least a part of the third deck of the second stack along the first direction, where the isolating structure extends through the first connecting layer, the second connecting layer, and the third connecting layer along the first direction.

In some implementations, the first conductive layer of the first deck of the first stack and the second conductive layer of the second deck of the first stack extend into the second stack along the second direction.

In some implementations, the semiconductor device further includes: a gate line structure extending through the first stack along the first direction; and channel structures extending through the first stack along the first direction.

In some implementations, the isolating structure further includes a filling layer surrounded by the dielectric layer of the isolating structure.

In some implementations, the first contact structure does not extend into the second deck of the second stack, and the second contact structure does not extend into the third deck of the second stack.

In some implementations, a bottom end of the third contact structure and a bottom end of a channel structure of the channel structures are at a same position along the first direction.

Another aspect of the present disclosure features a semiconductor device. The semiconductor device includes: a first stack of conductive layers and insulating layers alternating with each other along a first direction, where the first stack includes a first deck of conductive layers and insulating layers and a second deck of conductive layers and insulating layers; a second stack of dielectric layers and insulating layers alternating with each other along the first direction, where the second stack includes a first deck of dielectric layers and insulating layers and a second deck of dielectric layers and insulating layers; a first connecting layer connecting a first conductive layer of the first deck of the first stack with a first dielectric layer of the first deck of the second stack along a second direction perpendicular to the first direction; a second connecting layer connecting a second conductive layer of the second deck of the first stack with a second dielectric layer of the second deck of the second stack along the second direction; a first contact structure extending through the first deck of the second stack along the first direction, where the first contact structure extends through and is connected with the first connecting layer; and a second contact structure extending through the first deck and the second deck of the second stack along the first direction, where the second contact structure extends through the first connecting layer and the second connecting layer and is connected with the second connecting layer, and the second contact structure is isolated from the first connecting layer by a dielectric spacer.

In some implementations, the semiconductor device further includes: an isolating structure extending through the first deck of the second stack along the first direction, where the isolating structure extends through the first connecting layer and the second connecting layer along the first direction, and the isolating structure includes a dielectric layer.

In some implementations, the first stack further includes a third deck of conductive layers and insulating layers; the second stack further includes a third deck of dielectric layers and insulating layers; a third connecting layer connects a third conductive layer of the third deck of the first stack with a third dielectric layer of the third deck of the second stack along the second direction; a third contact structure extends through the first deck, the second deck, and the third deck of the second stack along the first direction, where the third contact structure extends through the first connecting layer, the second connecting layer, and the third connecting layer, the third contact structure is connected with the third connecting layer, and the third contact structure is isolated from the first connecting layer and the second connecting layer by dielectric spacers; and the isolating structure extends through the first deck and the second deck of the second stack along the first direction and extends through at least a part of the third deck of the second stack along the first direction, where the isolating structure extends through the first connecting layer, the second connecting layer, and the third connecting layer along the first direction.

In some implementations, the first conductive layer of the first deck of the first stack and the second conductive layer of the second deck of the first stack extend into the second stack along the second direction.

In some implementations, the semiconductor device further includes: a gate line structure extending through the first stack along the first direction; and channel structures extending through the first stack along the first direction.

In some implementations, the isolating structure further includes a filling layer surrounded by the dielectric layer.

A further aspect of the present disclosure features a method including forming a first stack of conductive layers and insulating layers alternating with each other along a first direction and a second stack of dielectric layers and insulating layers alternating with each other along the first direction, where the first stack includes a first deck of conductive layers and insulating layers and a second deck of conductive layers and insulating layers, and the second stack includes a first deck of dielectric layers and insulating layers and a second deck of dielectric layers and insulating layers; forming a first connecting layer and a second connecting layer, where the first connecting layer connects a first conductive layer of the first deck of the first stack with a first dielectric layer of the first deck of the second stack along a second direction perpendicular to the first direction, and the second connecting layer connects a second conductive layer of the second deck of the first stack with a second dielectric layer of the second deck of the second stack along the second direction; and forming an isolating structure extending through the first deck of the second stack along the first direction, where the isolating structure extends through the first connecting layer and the second connecting layer along the first direction, and the isolating structure includes a dielectric layer.

In some implementations, the first stack further includes a third deck of conductive layers and insulating layers; the second stack further includes a third deck of dielectric layers and insulating layers; the isolating structure extends through the first deck and the second deck of the second stack along the first direction and extends through at least a part of the third deck of the second stack along the first direction; and the method further includes: forming a third connecting layer connecting a third conductive layer of the third deck of the first stack with a third dielectric layer of the third deck of the second stack along the second direction; forming a first contact structure extending through the first deck of the second stack along the first direction, where the first contact structure extends through and is connected with the first connecting layer; forming a second contact structure extending through the first deck and the second deck of the second stack along the first direction, where the second contact structure extends through the first connecting layer and the second connecting layer and is connected with the second connecting layer, and the second contact structure is isolated from the first connecting layer by a dielectric spacer; and forming a third contact structure extending through the first deck, the second deck, and the third deck of the second stack along the first direction, where the third contact structure extends through the first connecting layer, the second connecting layer, and the third connecting layer, the third contact structure is connected with the third connecting layer, and the third contact structure is isolated from the first connecting layer and the second connecting layer by dielectric spacers.

In some implementations, the method further includes: before forming the first stack and the second stack, forming a third stack of dielectric layers and insulating layers alternating with each other along the first direction, where the third stack includes a first deck of dielectric layers and insulating layers, a second deck of dielectric layers and insulating layers, and a third deck of dielectric layers and insulating layers, and where: forming the first stack and the second stack includes: replacing portions of the dielectric layers in the third stack by conductive layers; forming the first stack using the conductive layers and the insulating layers in the third stack between the conductive layers; and forming the second stack using remaining portions of the dielectric layers in the third stack and the insulating layers between the remaining portions of the dielectric layers in the third stack.

In some implementations, forming the first contact structure, the second contact structure, and the third contact structure includes forming a first contact hole, a second contact hole, and a third contact hole extending along the first direction, where the first contact hole extends through the first deck of the third stack, the second contact hole extends through the second deck of the third stack, and the third contact hole extends through the third deck of the third stack; and forming the isolating structure includes forming an isolating hole extending along the first direction, where the isolating hole extends into the first deck of the third stack to expose a first dielectric layer of the first deck of the third stack, and where the method further includes: depositing a dielectric layer on an inner wall of the isolating hole; removing a portion of a first dielectric layer of the first deck of the third stack to form a first connecting space connected to the isolating hole, where the first contact hole, the second contact hole, and the third contact hole extend through the first connecting space along the first direction; filling a filler material into the first connecting space; forming a first dielectric spacer between the second contact hole and the filler material in the first connecting space and a second dielectric spacer between the third contact hole and the filler material in the first connecting space; deepening the isolating hole along the first direction, where the isolating hole extends into the second deck of the third stack to expose a second dielectric layer of the second deck of the third stack; removing a portion of the second dielectric layer of the second deck of the third stack to form a second connecting space connected to the isolating hole, where the second contact hole and the third contact hole extend through the second connecting space along the first direction; filling the filler material into the second connecting space; forming a third dielectric spacer between the third contact hole and the filler material in the second connecting space; deepening the isolating hole along the first direction, where the isolating hole extends into the third deck of the third stack to expose a third dielectric layer of the third deck of the third stack; removing a portion of the third dielectric layer of the third deck of the third stack to form a third connecting space connected to the isolating hole, where the third contact hole extend through the third connecting space along the first direction; filling the filler material into the third connecting space; and filling a sacrificial material into the isolating hole.

In some implementations, the conductive layers are formed by: forming a gate line slit extending through the third stack along the first direction; forming tunnels between the insulating layers in the third stack by filling an etchant into the gate line slit to remove a portion of each dielectric layer of the third stack, where the tunnels expose the filler material in the first connecting space, the second connecting space, and the third connecting space, the first dielectric layer of the first deck of the second stack includes a remaining portion of the first dielectric layer of the first deck of the third stack, the second dielectric layer of the second deck of the second stack includes a remaining portion of the second dielectric layer of the second deck of the third stack, and the third dielectric layer of the third deck of the second stack includes a remaining portion of the third dielectric layer of the third deck of the third stack; forming a first recess, a second recess, a third recess by removing a portion of the filler material in the first connecting space, the second connecting space, and the third connecting space, respectively; and forming the conductive layers between the insulating layers in the third stack by depositing at least a conductive material in the tunnels, the first recess, the second recess, and the third recess.

In some implementations, the method further includes: removing the sacrificial material in the isolating hole; and removing the filler material in the first connecting space, the second connecting space, and the third connecting space, and where: forming the first connecting layer, the second connecting layer, and the third connecting layer includes depositing at least a conductive material into the first connecting space, the second connecting space, and the third connecting space respectively through the isolating hole; forming the isolating structure further includes filling a dielectric material into the isolating hole; and forming the first contact structure, the second contact structure, and the third contact structure further includes filling at least a conductive material into the first contact hole, the second contact hole, and the third contact hole.

### BRIEF DESCRIPTION OF DRAWINGS

FIGS. 1A-1C illustrate an example semiconductor device.

FIGS. 2A-2O illustrate an example process of manufacturing a semiconductor device.

FIG. 3 illustrates a flow chart of an example process of manufacturing a semiconductor device.

FIG. 4 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to a demand for cheaper memory devices with a higher density, a memory device (e.g., a 3D NAND flash memory) can be formed to have a large number of layers with a high aspect ratio. For example, the memory device can have multiple decks, and each deck can have multiple conductive layers and insulating layers. Each conductive layer can be connected to a contact structure. The large number of layers and the high aspect ratio of such memory devices may bring challenges to the manufacturing process. For example, the large number of layers of the memory devices results in an increased number of contact structures connected to the layers. In other words, the large number of contact structure may cause an increased area of the connection region, which leads to a lower core memory area. In another example, stress issues caused by the conductive filling in the contact structure can become more severe and cause the leakage between the contact structure and the conductive layers. In another example, the high aspect ratio may cause current leakage between the conductive layers of the multiple decks.

In one or more implementations of the present disclosure, an example semiconductor device is provided. The semiconductor device includes a first stack, where the first stack includes a first deck of alternating conductive layers and insulating layers and a second deck of alternating conductive layers and insulating layers along a first direction. The semiconductor further includes a second stack, where the second stack includes a first deck of alternating dielectric layers and insulating layers and a second deck of alternating dielectric layers and insulating layers along the first direction. The semiconductor device further includes a first connecting layer connecting a first conductive layer of the first deck of the first stack with a first dielectric layers of the first deck of the second stack along a second direction perpendicular to the first direction. The semiconductor device further includes a second connecting layer connecting a second conductive layer of the second deck of the first stack with a second dielectric layer of the second deck of the second stack along the second direction. The semiconductor device further includes an isolating structure extending through the first deck of the second stack along the first direction, where the isolating structure extends through the first connecting layer and the second connecting layer along the first direction. The semiconductor device further includes a first contact structure extending through the first deck of the second stack along the first direction, where the first contact structure extends through and is connected with the first connecting layer, and a second contact structure extending through the first deck and the second deck of the second stack along the first direction, wherein the second contact structure extends through the first connecting layer and the second connecting layer and is connected with the second connecting layer, and the second contact structure is isolated from the first connecting layer by a dielectric spacer.

Implementations of the present disclosure can provide one or more of the following technical advantages and/or benefits. First, in the example semiconductor device described above, the semiconductor device includes multiple isolating structures. Adjacent contact structures associated with the same isolating structure are coupled to multiple conductive layers respectively through connecting layers. The connecting layers are formed using an isolating hole at the same position as the isolating structure in the fabrication process. Thus, the length of a connection region of the described device is reduced, and the area of a core region of the described device is increased. Second, the first conductive layer and the second conductive layer of the first stack extend into the second stack to reduce the leakage current between the conductive layer and the connecting layer. Third, the isolating structure is filled with a dielectric material, thereby mitigating the stress effect and reducing the leakage current between the contact structure and the conductive layer. The isolating structure can help release stress in the gate line structure and can allow the conductive layer filling process to be performed in separate steps, thereby improving the quality and reliability of the conductive layers.

The techniques can be applied to any semiconductor structures or devices that are configured to avoid electric leakage or breakdown, e.g., between conductive layers or components. The techniques can be applied to various types of semiconductor devices, volatile memory devices, such as Dynamic random-access memory (DRAM) memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), solid-state drives (SSDs), or embedded systems, among others.

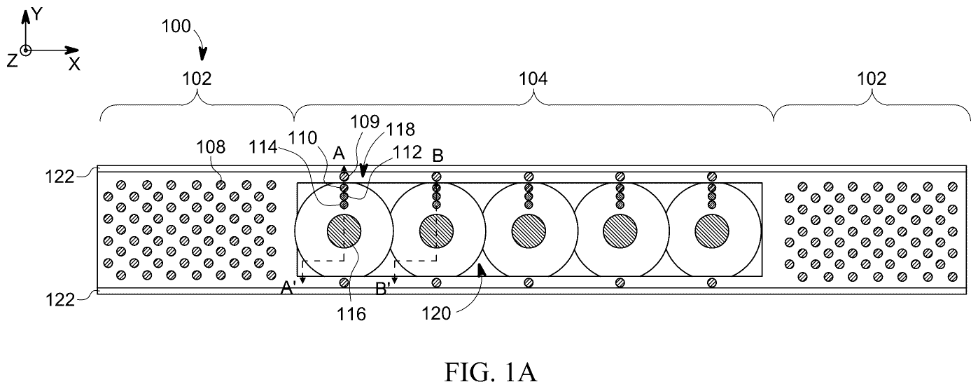

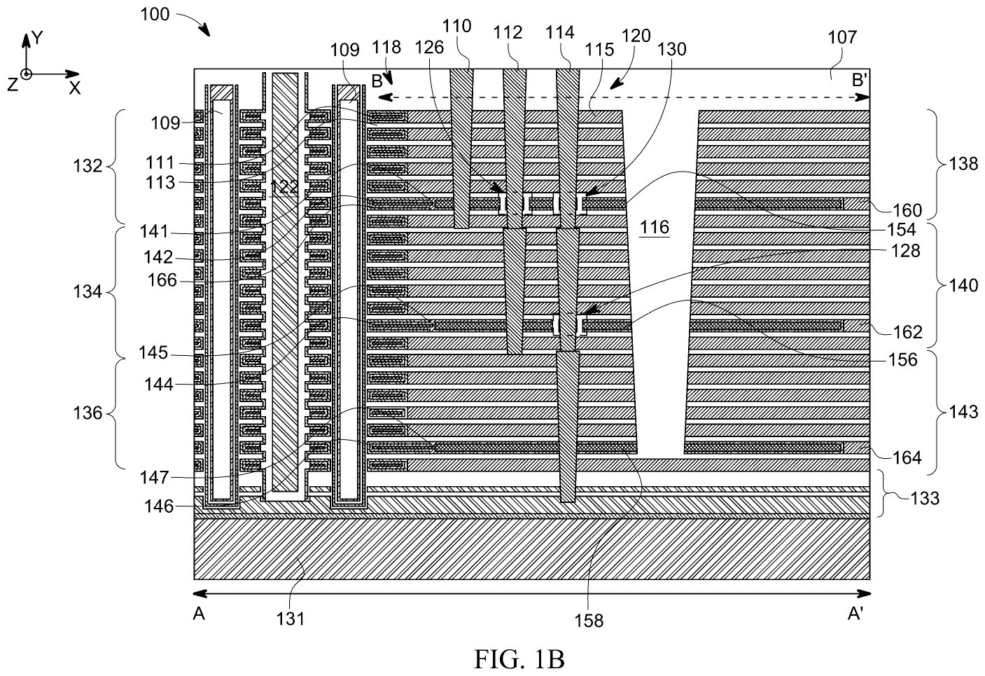

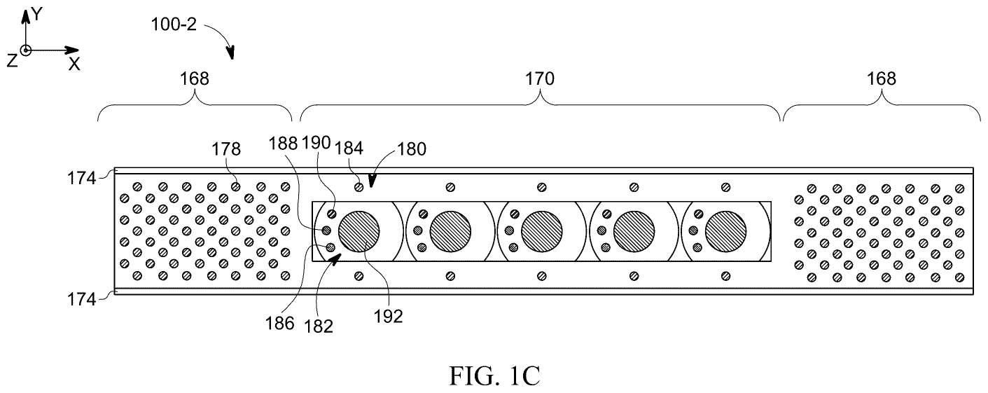

It is noted that X, Y, and Z axes (also referred to as X, Y, and Z directions) are included in FIGS. 1A-1C to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIGS. 1A-1C illustrate example semiconductor devices. FIG. 1A illustrates a top view of an example semiconductor device 100. In some implementations, the semiconductor device 100 can be a memory device, such as a three-dimensional (3D) NAND memory device. The semiconductor device 100 can include one or more array regions 102 and one or more connection regions 104 configured to provide conductive connections for the one or more array regions. In some implementations, as shown in FIG. 1A, the semiconductor device 100 includes a connection region 104 in between two array regions 102 along a first horizontal direction (e.g., the X direction). It is understood that the example in FIG. 1A is for illustration purpose and is not intended to be construed in a limiting sense. In practice, any suitable arrangement of various regions in the semiconductor device 100 can be applied. In some instances, the semiconductor device can have two connection regions 104 and an array region 102 arranged between the two connection regions 104 along the X direction. In some other instances, the semiconductor device 100 can have an array region 102 and a connection region 104 adjacent to the array region 102 along the X direction.

The semiconductor device 100 includes a stack 118 of alternating conductive layers and insulating layers (e.g., conductive layers 111 and insulating layers 113 as shown in FIG. 1B). In some implementations, a part of the stack 118 can be in the array region 102, and another part of the stack 118 can be in the connection region 104. The semiconductor device 100 further includes a stack 120 of alternating dielectric layers and insulating layers (e.g., dielectric layers 115 and insulating layers 113 as shown in FIG. 1B). In some implementations, the stack 120 can be in the connection region 104. The stack 118 is connected to the stack 120.

The semiconductor device 100 can include an array of channel structures 108 extending through the stack 118 in the array region 102 along a vertical direction (e.g., the Z direction) perpendicular to the first horizontal direction. Each channel structure 108 can be used to form a string of memory cells coupled in serial along the vertical direction (e.g., the Z direction). In some examples, the channel structure 108 can be in the shape of a cylinder or a pillar (not shown in FIG. 1A-C), and can include a high-K layer, a block layer surrounded by the high-K layer, a charge trapping layer (or a storage layer) surrounded by the block layer, a tunneling layer surrounded by the charge trapping layer, a channel layer surrounded by the tunneling layer, a core filler layer surrounded by the channel layer, and a channel plug formed above the core filler layer and being in contact with the channel layer. In some implementations, the channel layer can include silicon, such as amorphous silicon, polysilicon, or single crystalline silicon, the tunneling layer can include silicon oxide, silicon nitride, or any combination thereof, the blocking layer can include silicon oxide, silicon nitride, high-K dielectrics, or any combination thereof, and the charge trapping layer can include silicon nitride, silicon oxynitride, silicon, or any combination thereof. In some implementations, the tunneling layer, the charge trapping layer, and the blocking layer, collectively referred to as a memory film, can include ONO dielectrics (silicon Oxide-silicon Nitride-silicon Oxide).

In some implementations, the semiconductor device 100 can include dummy channel structures 109 (also referred to as dummy memory strings), as shown in FIG. 1B, for process variation control during fabrication and/or for additional mechanical support. The dummy channel structures 109 can extend through the stack 118 in the connection region 104. For example, some dummy channel structures can be in an edge or peripheral area of the connection region 104. In some implementations, the dummy channel structures 109 can be in one or more dummy regions or peripheral regions (not shown in FIGS. 1A-C). In some examples, the dummy channel structure 109 can be in the shape of a cylinder or a pillar (as shown in FIG. 1B). In some implementations, the channel structure 108 and the dummy channel structure 109 can have similar or the same structure and can be formed in the same manufacturing process.

The semiconductor device 100 can include one or more gate line structures 122. Each gate line structure 122 can extend in the X direction. The gate line structure 122 can extend into both the array region 102 and the connection region 104. In some implementations, the gate line structures 122 can divide an array region into multiple memory blocks. In some implementations, the gate line structure 122 can function as a common source contact for the channel structures 108 in the array region 102. In some implementations (not shown in FIG. 1A), the gate line structure 122 can further include one or more segments extending along the X direction. In some instances, the edge area of the connection region 104 is adjacent to an array region 102. In some other instances, the edge area of the connection region 104 is adjacent to a gate line structure (e.g., gate line structure 122 as shown in FIG. 1A). In some implementations, the dummy channel structures are in the array region 102 (e.g., an area adjacent to the connection region 104).

The semiconductor device 100 can include a first contact structure 110 and a second contact structure 112 in the connection region 104. The first contact structure 110 and the second contact structure 112 can extend through at least a part of the stack 120 along the Z direction. In some implementations, as shown in FIG. 1B, a corresponding contact structure (e.g., the first contact structure 110, and the second contact structure 112) can be configured to connect to one of the conductive layers in a corresponding deck of the stack 118. In some other instance, as shown in FIG. 1A, the semiconductor device can include a third contact structure 114 in the connection region 104. The third contact structure 114 can also extend through at least a part of the stack 120 along the Z direction. The third contact structure 114 is connected to one of the conductive layers in a corresponding deck of the stack 118. In some other instance (not shown in FIGS. 1A-C) the stack 118 includes one or more decks of alternating conductive layers 111 and insulating layers 113, where each deck of alternating conductive layers 111 and insulating layers 113 of the stack 118 has a conductive layer connected to at least one corresponding contact structure. The stack 120 has one or more decks of alternating dielectric layers 115 and insulating layers 113 corresponding to the one or more decks in the stack 118. The semiconductor device 100 can further include one or more isolating structures 116 in the connection region 104. Each isolating structure 116 can extend into the stack 120 along the Z direction and can be used for conductive layer access during fabrication and/or for additional mechanical support.

FIG. 1B illustrates a cross-sectional view of the semiconductor device 100 along cut line AA′ of FIG. 1A. The semiconductor device 100 includes a substrate 131, one or more spacer layers 133 stacked on top of the substrate 131 along the Z direction, the stack 118 of alternating conductive layers 111 and insulating layers 113, and the stack 120 of alternating dielectric layers 115 and insulating layers 113. In some implementations, the dielectric layers 115 can also be referred to as sacrificial layers. Each insulating layer 113 can have a portion between two adjacent conductive layers 111 in the stack 118 and another portion between two adjacent dielectric layers 115 in the stack 120. The stack 118 and the stack 120 are provided over one or more spacer layers 133. The substrate 131 can be any suitable semiconductor substrate having any suitable semiconductor material, such as monocrystalline, polycrystalline or single crystalline semiconductor. For example, the substrate 131 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. In some implementations, the substrate 131 can be removed from the semiconductor device 100 in a later process of manufacturing the semiconductor device 100. In some implementation, the spacer layers 133 can include one or more semiconductor layers and one or more dielectric layers stacked on top of each other. The semiconductor device 100 can include a top layer 107 made of an isolating material (e.g., oxide).

The stack 118 can extend in the second horizontal direction (e.g., the Y direction) that is parallel to a top surface of the substrate 131 and perpendicular to the first horizontal direction (e.g., the X direction). The conductive layers 111 and the insulating layers 113 can alternate in the vertical direction (e.g., Z direction) perpendicular to the first horizontal direction and the second horizontal direction. It should be noted that the number of the conductive layers 111 and the insulating layers 113 shown in FIG. 1B is for illustration only and that any suitable number of the conductive layers 111 and the insulating layers 113 can be included in the stack 118.

In some implementations, the stack 118 and the stack 120 each can include one or more decks. For example, as shown in FIG. 1B, the stack 118 can include a deck 132, and a deck 134. The deck 132 and the deck 134 includes one or more of the conductive layers 111 and insulating layers 113 in the stack 118. The deck 132 can be stacked on the deck 134 along the Z direction. In some instances, as shown in FIG. 1B, the stack 118 can include another deck 136, which includes one or more of the conductive layers 111 and insulating layers 113 in the stack 118. The deck 132 and deck 134 can be stacked on the deck 136 along the Z direction. In some implementations, the deck 132 can be the deck that is farthest away from the substrate 131 among decks of the semiconductor device 100. Each deck in the stack 118 is connected to a corresponding deck in the stack 120 along the Y direction. For example, as shown in FIG. 1B, the deck 132 of the stack 118 is connected to a first deck 138 of the stack 120, the deck 134 of the stack 118 is connected to a second deck 140 of the stack 120, and the deck 136 of the stack 118 is connected to a third deck 143 of the stack 120. The first deck 138, the second deck 140, and the third deck 143 includes one or more of the dielectric layers 115 and insulating layers 113. The number of dielectric layers in the stack 120 is the same as the number of conductive layers of the stack 118. In some other implementations (not shown in FIG. 1B), the stack 118 and the stack 120 each can include more decks stacked along the Z direction. The conductive layers 111 can include any suitable conducting material, such as tungsten (W), cobalt (Co), copper (Cu), aluminum (Al), titanium nitride (TiN), polycrystalline silicon (polysilicon), doped silicon, silicides, or any combination thereof. The insulating layers 113 can include a dielectric material, such as silicon oxide, silicon nitride, silicon oxynitride, or any combination thereof. In some implementations, the insulating layers 113 can also include high-K dielectric materials, such as hafnium oxide, zirconium oxide, aluminum oxide, tantalum oxide, lanthanum oxide, or any combination thereof. In some implementations, the dielectric layers 115 can include a dielectric material different from the dielectric material of the insulating layers 113. For example, the insulating layers 113 can include silicon oxide, and the dielectric layers 115 can include silicon nitride.

In some implementations, as illustrated in FIG. 1B, the stack 118 includes liner layers 166. A liner layer 166 can cover part or all sides of a corresponding conductive layer 111 and be between the conductive layer 111 and two insulating layers 113 adjacent to the corresponding conductive layer 111. The liner layer 166 can include a high-K dielectric material (e.g., Al₂O₃). In some examples, the conductive layer 111 includes a metallic material (e.g., W) and an adhesive material (e.g., TiN), and the adhesive material can be deposited between the metallic material and the high-K dielectric material. In some examples, the conductive layer 111 includes the metallic material (e.g., W), and the liner layer 166 includes the adhesive material (e.g., TiN) and the high-K dielectric material.

The stack 120 include dielectric layers 115 and insulating layers 113 alternating with each other along the vertical direction (e.g., Z direction). The insulating layers 113 can extend into both the stack 118 and the stack 120 along the second horizontal direction (e.g., Y direction) in the connection region 104. A dielectric layer 115 in the stack 120 can extend to and be in contact with a corresponding conductive layer 111 (or a liner layer 166 surrounding the corresponding conductive layer 111) in the stack 118. The stack 120 can include connecting layers corresponding to each deck of the stack 120. For example, as shown in FIG. 1B, a first connecting layer 154 of the first deck 138 of the stack 120 is in connection with a first dielectric layer 160 of the stack 120 and a first conductive layer 142 of the deck 132 of the stack 118 along the Y direction. In some implementations, as shown in FIG. 1B, the first conductive layer 142 is surrounded by an adhesion liner layer and the first connecting layer 154 is surrounded by an adhesion liner layer. A second connecting layer 156 of the second deck 140 of the stack 120 is in connection with a second dielectric layer 162 of the stack 120 and a second conductive layer 144 of the deck 134 of the stack 118 along the Y direction. In some implementations, as shown in FIG. 1B, the second conductive layer 144 is surrounded by an adhesion liner layer and the second connecting layer 156 is surrounded by an adhesion liner layer. In some instances, as shown in FIG. 1B, the stack 120 can include a third connecting layer 158 in the third deck 143 of the stack 120. The third connecting layer 158 of the third deck 143 of the stack 120 is in connection with a third dielectric layer 164 of the third deck 143 of the stack 120 and a third conductive layer 146 of the deck 132 of the stack 118 along the Y direction. In some implementations, as shown in FIG. 1B, the third conductive layer 146 is surrounded by an adhesion liner layer and the third connecting layer 158 is surrounded by an adhesion liner layer. Each conductive layer in the stack 118 connected to a corresponding connecting layer extends into the stack 120 along the Y direction. For example, the first connecting layer 154 is in contact with an end 141 of the first conductive layer 142 along the Y direction. In another example, the second connecting layer 156 is in contact with an end 145 of the second conductive layer 144 along the Y direction. In another example, the third connecting layer 158 is in contact with an end 147 of the third conductive layer 146. The end 141 is between two dielectric layers 115 of the first deck 138 of the stack 120, the end 145 is between two dielectric layers 115 of the second deck 140 of the stack 120, and the end 147 is between two dielectric layers 115 of the third deck 143 of the stack 120. In some other instance (not shown in FIG. 1B), the number of conductive layers in each deck of the stack 118 and the number of corresponding connecting layers in each deck of the stack 120 is greater than one. The connecting layers 154, 156, and 158 can include any suitable conducting material, such as tungsten (W), cobalt (Co), copper (Cu), aluminum (Al), titanium nitride (TiN), polycrystalline silicon (polysilicon), doped silicon, silicides, or any combination thereof.

The gate line structure 122 can extend through the stack 118 along the vertical direction (e.g., the Z direction). In some implementations, as shown in FIG. 1B, the gate line structure 122 can extend from the top layer 107 into one of the one or more spacer layers 133 along the Z direction. The dummy channel structure 109 also can extend through the stack 118 along the vertical direction (e.g., the Z direction). In some implementations, as shown in FIG. 1B, the dummy channel structure 109 can extend into one of the one or more spacer layers 133 along the Z direction. The contact structures of the stack 120 extend through at least a part of the stack 120 (e.g., a set of dielectric layers 115 and insulating layers 113 of the stack 120) along the Z direction.

The semiconductor device 100 includes contact structures extending through at least a portion of the stack 120. Each contact structures of the stack 120 is connected with at least one of the corresponding connecting layers of the stack 120. For example, as illustrated in FIG. 1B, the first contact structure 110 extends through the first deck 138 and the first connecting layer 154 of the stack 120 along the Z direction and is connected to the first connecting layer 154, where the first contact structure 110 does not extend into the second deck 140 of the stack 120. The second contact structure 112 extends through the first deck 138, the first connecting layer 154, the second deck 140, and the second connecting layer 156 of the stack 120 along the Z direction and is connected to the second connecting layer 156, where the second contact structure 112 does not extend into the third deck 143 of the stack 120. The second contact structure 112 is isolated from the first connecting layer 154 by a dielectric spacer 126.

In some other instance, shown in FIG. 1B, the semiconductor device can include the third contact structure 114 that extends through the first deck 138, the first connecting layer 154, the second deck 140, the second connecting layer 156, the third deck 143, and the third connecting layer 158 of the stack 120 along the Z direction and is connected to the third connecting layer 158, where the bottom end of third contact structure 114 extends into one of the one or more spacer layers 133 and is at a same position as the bottom end of the dummy channel structure 109 in the connection region 104 and the bottom end of the channel structure 108 in the array region 102 along the Z direction. The bottom ends of the third contact structure 114, the dummy channel structure 109, and the channel structure 108 are disposed at different locations in the X-Y plane. The third contact structure 114 is isolated from the first connecting layer 154 by a dielectric spacer 130 and the second connecting layer 156 by a dielectric spacer 128. The dielectric spacers 126, 128 and 130 can include same dielectric material as the insulating layer 113. In some other instance (not shown in FIG. 1B), the stack 120 has various decks of alternating dielectric layers 115 and insulating layers 113 with corresponding decks of alternating conductive layers 111 and insulating layers 113 in the stack 118 connected to the stack 120. Each of the various decks of the stack 120 has at least one contact structure connected to one or more corresponding connecting layers in the deck of the stack 120, where the one or more connecting layer is connected to one or more conductive layer of the corresponding deck of the stack 118. The contact structures of various decks of the stack 120 extend into one deck below the corresponding deck and are in contact with one of the dielectric layers 115 or insulating layers 113 of the deck below the corresponding deck of the stack 120 and is connected to the one or more corresponding connecting layers in the corresponding deck of the stack 120. The contact structures of various decks of the stack 120 extend through and isolate from the connecting layers above the corresponding deck of the stack 120 with dielectric spacers. In some implementations, as shown in FIG. 1A, the contact structures 110, 112, and 114 are aligned along the Y direction. For example, the contact structures 110, 112, and 114 can be aligned with the isolating structure 116 along the Y direction. Another example arrangement of the contact structures is illustrated in FIG. 1C.

The semiconductor device 100 can include the isolating structure 116 extending into the stack 120. As shown in FIG. 1B, the isolating structure 116 extends through the first deck 138 of the stack 120, where the isolating structure 116 extends through the first connecting layer 154 and the second connecting layer 156 along the Z direction. The isolating structure 116 includes a dielectric layer and a filling layer (not shown in FIGS. 1A-C). In some implementations, the dielectric layer of the isolating structure 116 can include silicon oxide, silicon nitride, high-K dielectrics, or any combination thereof, and the filling layer of the isolating structure 116 can include any structural support material such as poly silicon, carbon, silicon oxide, silicon nitride, or any combination thereof. The dielectric layer of the isolating structure 116 is in contact with the dielectric layers 115, insulating layers 113, and the connecting layers 154, 156, 158 of the stack 120. In some implementations, the isolating structure 116 extends through the first deck 138 and the second deck 140 of the stack 120 and extends into the third deck 143 of the stack 120. The isolating structure 116 is connected to one of the dielectric layers 115 of the third deck 143 of the stack 120. In some implementations, the isolating structure 116 is in contact with the connecting layers 154, 156, 158 of the corresponding decks 138, 140, and 143 of the stack 120 along the Y direction.

FIG. 1C illustrates an example semiconductor device 100-2, which can be another implementation of the semiconductor device 100. The semiconductor device 100-2 includes a connection region 170 in between two array regions 168 along a first horizontal direction (e.g., the X direction). Each connection region 170 can be similar to, or as same as, the connection region 104 of the semiconductor device 100. Each array region 168 can be similar to, or as same as, the connection region 104 of the semiconductor device 100. Each channel structure 178 in the array region 168 can be similar to, or as same as, the channel structure 108 in the semiconductor device 100. Each dummy channel structure 184 in the connection region 170 can be similar to, or as same as, the dummy channel structure 109 in the semiconductor device 100. Each gate line structure 174 can be similar to, or as same as, the gate line structure 122 in the semiconductor device 100. The semiconductor device 100-2 has a stack 180 of conductive layers and insulating layers altering with each other along the Z direction similar to the stack 118 of the semiconductor device 100. The semiconductor device can include a stack 182 of the dielectric layers and insulating layers alternating with each other along the Z direction similar to the stack 120 of the semiconductor device 100. An isolating structure 192 extends through the stack 182 similar to the isolating structure 116 of the semiconductor device 100. Contact structures 186, 188, and 190 can be similar to the contact structures 110, 112, and 114 of FIG. 1B. The arrangement of the contact structures 186, 188, and 190 is different from that of the contact structures 110, 112, and 114. Instead of being aligned along the Y direction, the contact structures 186, 188, and 190 can be arranged along a circle surrounding the isolating structure 192. It is understood that the arrangements of the contact structures shown in FIGS. 1B-1C are for illustration purpose and is not intended to be construed in a limiting sense. In practice, any suitable arrangement can be applied to the contact structures of the semiconductor device 100 or the semiconductor device 100-2.

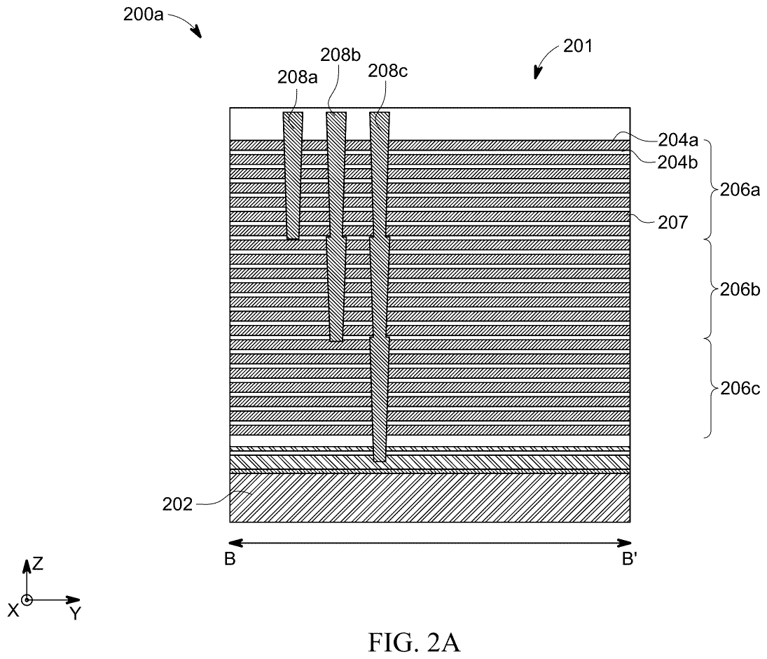

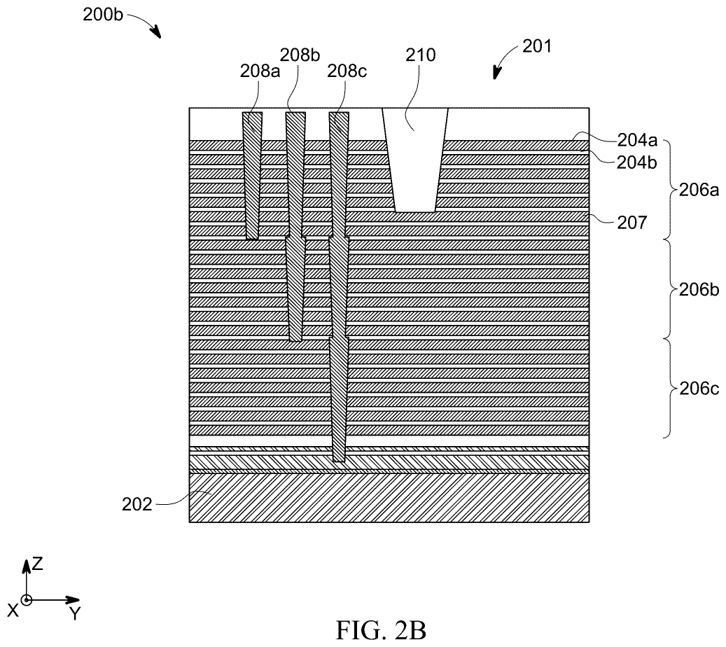

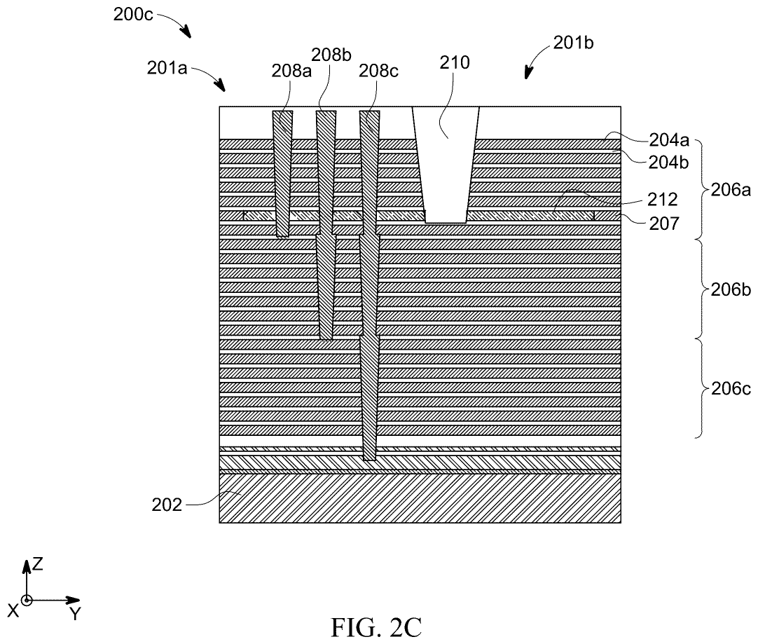

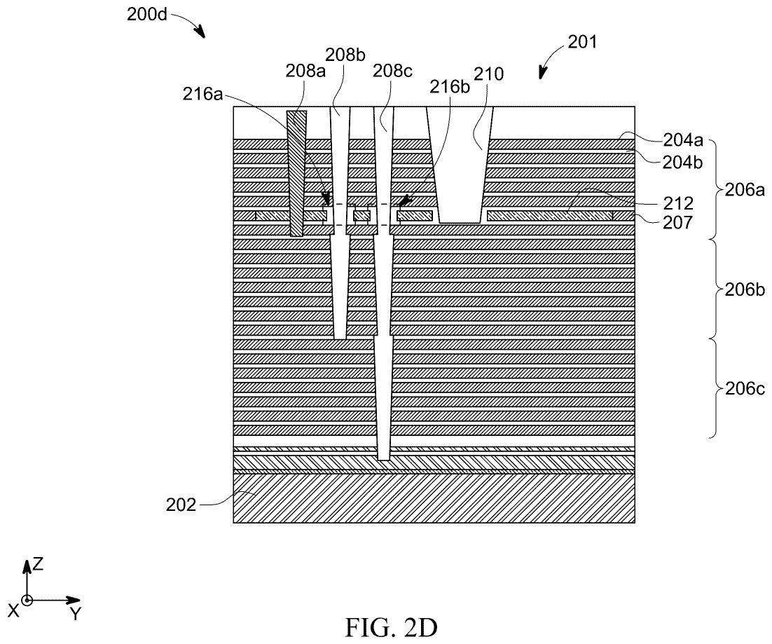

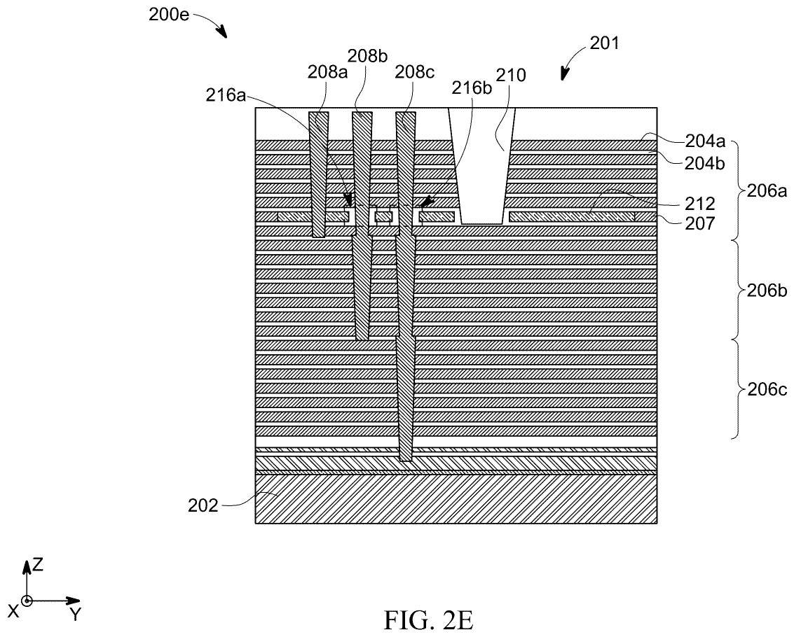

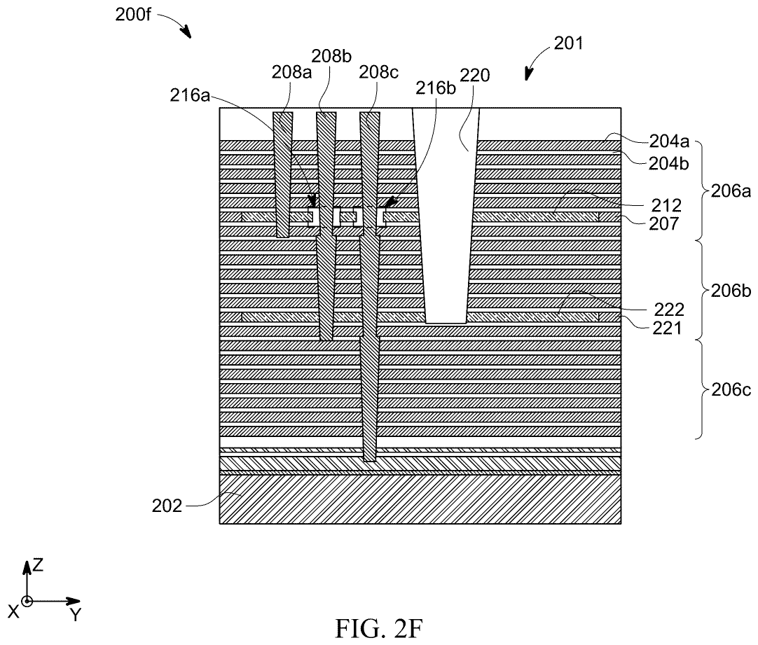

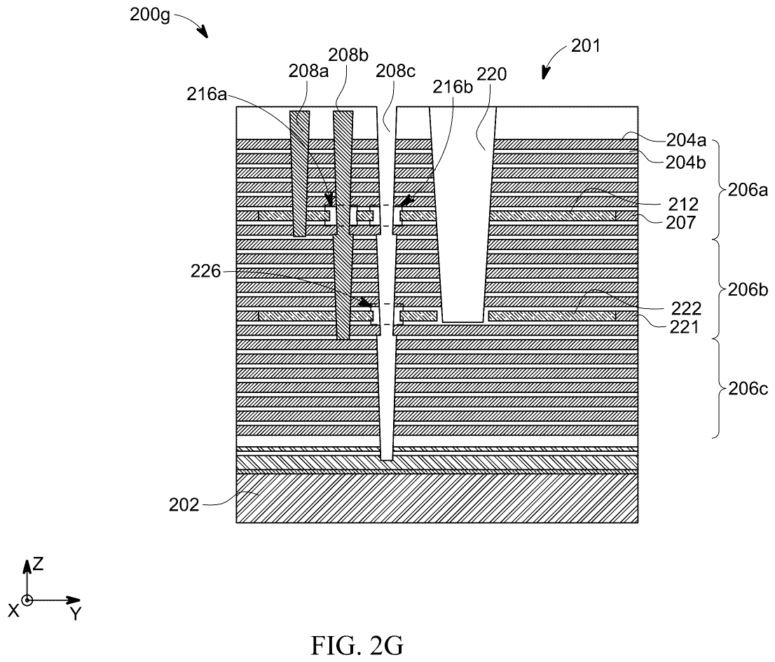

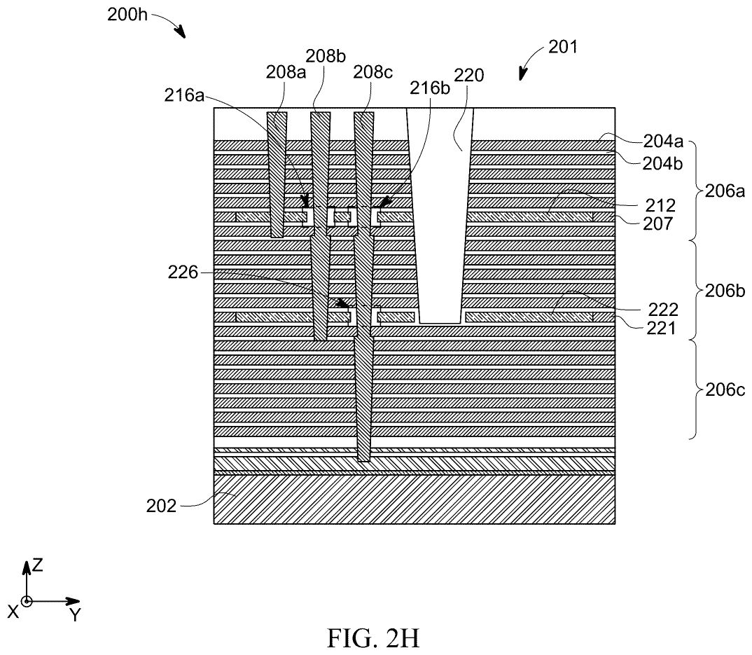

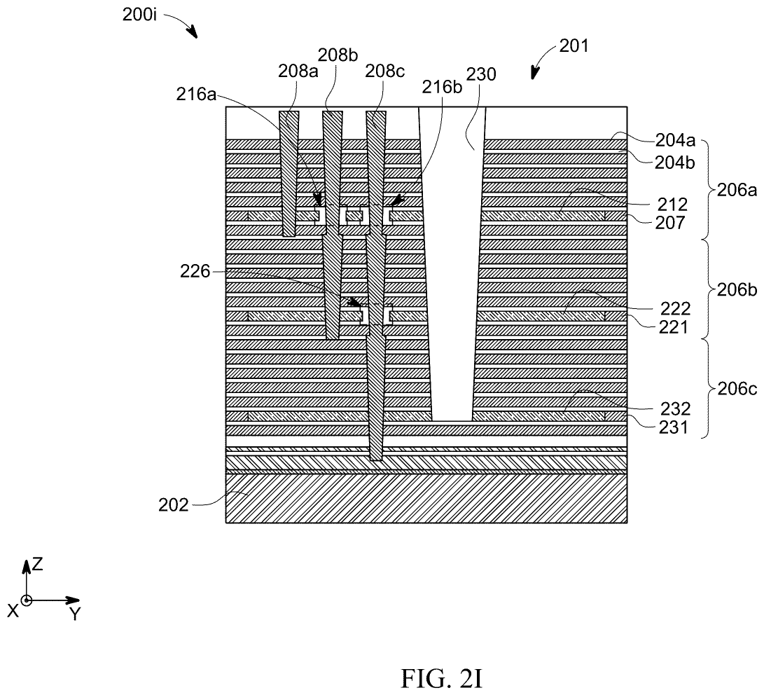

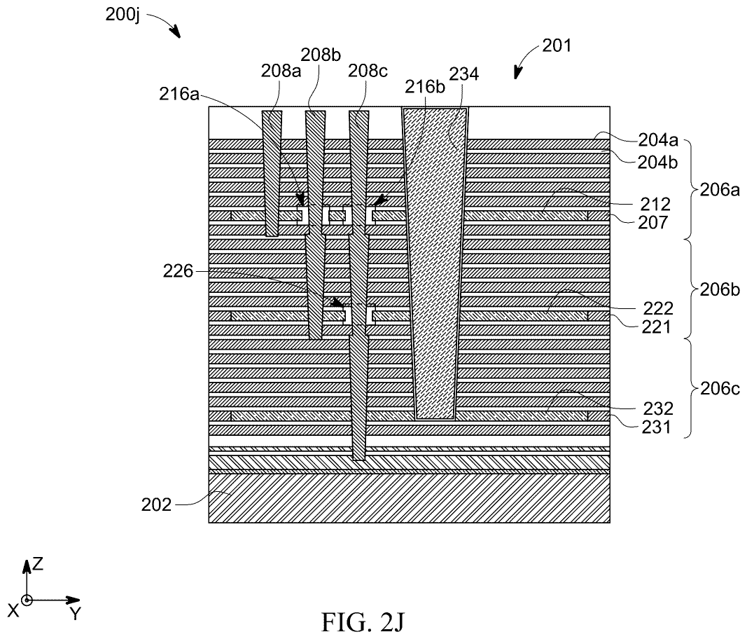

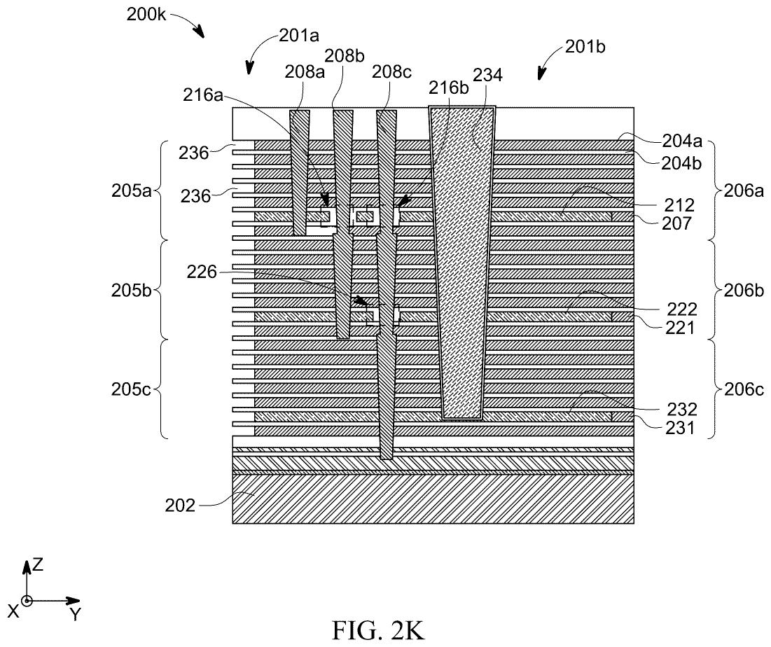

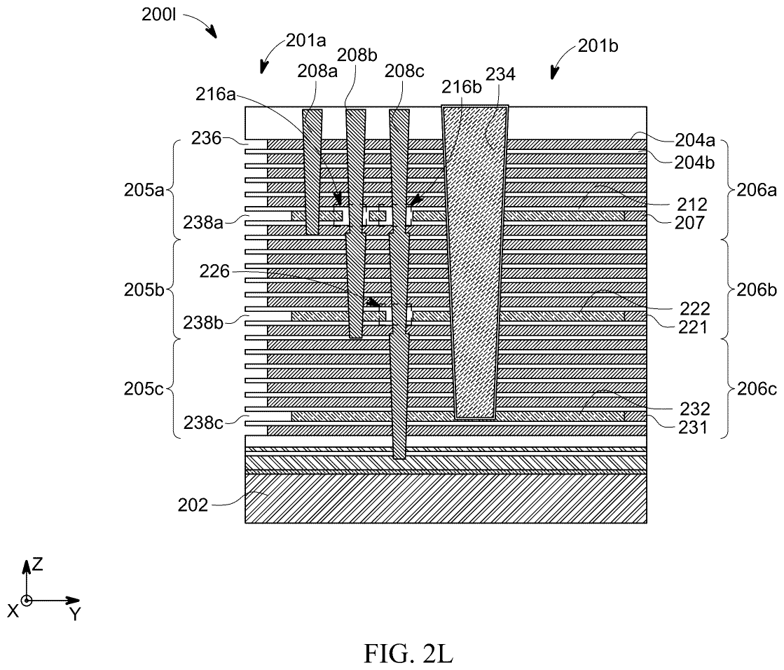

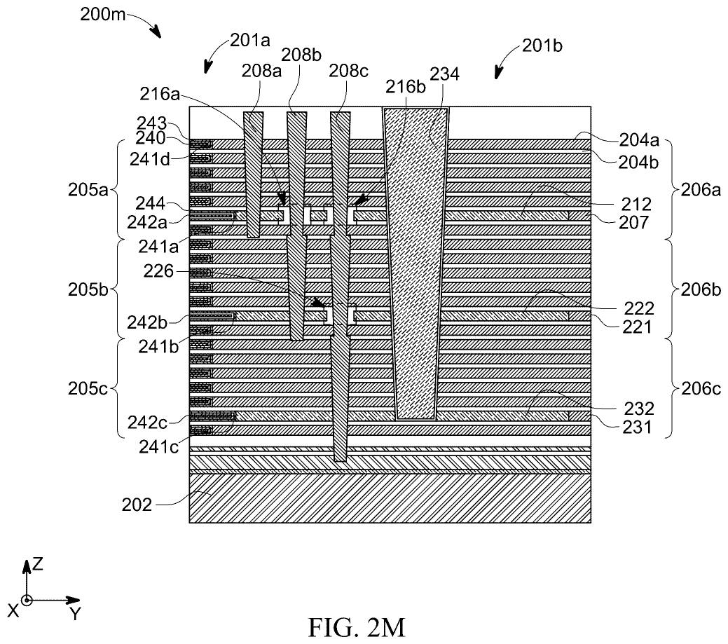

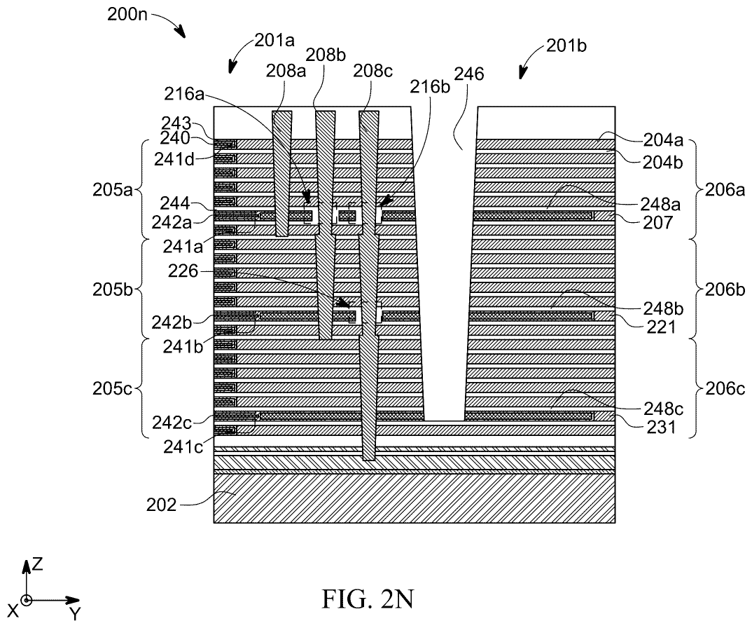

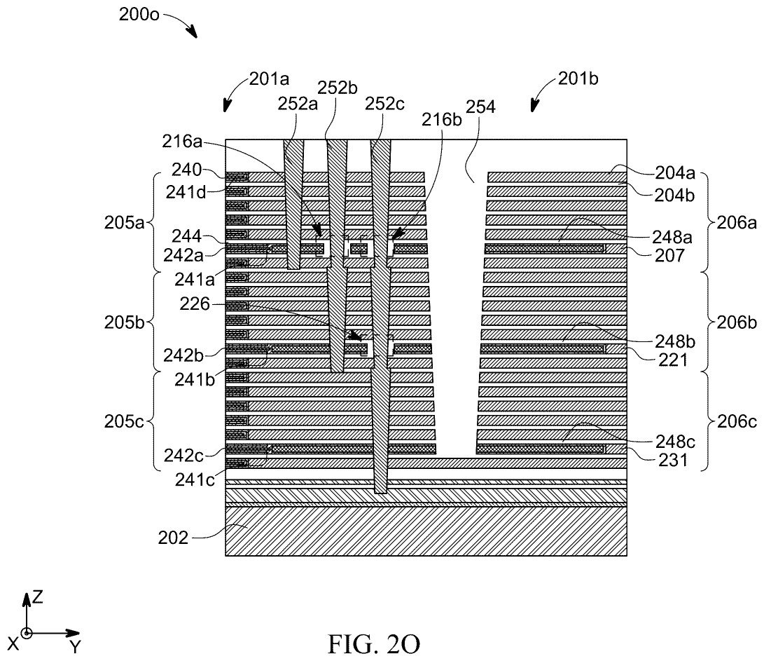

FIGS. 2A-2O illustrate an example process of fabricating a semiconductor device, such as the semiconductor device 100 or the semiconductor device 100-2 as illustrated in FIGS. 1A-1C. Specifically, FIGS. 2A-2O illustrate cross-sectional views of example semiconductor structures along the cut line BB′ of FIGS. 1A-1B.

As shown in FIG. 2A, a semiconductor structure 200a is formed. The semiconductor structure 200a includes a substrate 202 and a stack 201 of alternating dielectric layers 204a and insulating layers 204b. Each dielectric layer 204a can also be referred to as a sacrificial layer. The stack 201 includes a first deck 206a, a second deck 206b, and a third deck 206c. Each of the decks 206a, 206b, and 206c includes a subset of the stack 201 of dielectric layers 204a and insulating layers 204b. The dielectric layers 204a and insulating layers 204b can alternate with each other along the vertical direction (e.g., the Z direction). The substrate 202 and each of the dielectric layers 204a and insulating layers 204b can extend in the X-Y plane. The semiconductor structure 200a can formed by, for example, depositing the first deck 206a, the second deck 206b, and the third deck 206c of dielectric layers 204a and insulating layers 204b on top of the substrate 202. The semiconductor structure 200a can include a contact hole 208a, a contact hole 208b, and a contact hole 208c extending along the Z direction. The contact hole 208a extends through the first deck 206a of the stack 201, where the contact hole 208a does not extend into the second deck 206b of the stack 201, the contact hole 208b extends through the second deck 206b of the stack 201, where the contact hole 208b does not extend into the third deck 206c of the stack 201, and the contact hole 208c extends through the third deck 206c of the stack 201. The insulating layers 204b can include dielectric material, such as silicon oxide, silicon nitride, silicon oxynitride, or any combination thereof. In some implementations, the dielectric layers 204a can include a dielectric material different from the dielectric material of the insulating layers 204b. The contact holes 208a, 208b, and 208c can be filled with a filler material different from the dielectric material of the dielectric layer 204a and the dielectric material of the insulating layers 204b. For example, the insulating layers 204b can include silicon oxide, the dielectric layers 204a can include silicon nitride, and the filler material in the contact holes 208a, 208b, and 208c can include polysilicon.

FIG. 2B illustrates a semiconductor structure 200b. The semiconductor structure 200b can be formed by forming an isolation hole 210 in the stack 201 by an etching process. The isolation hole 210 can extend from a top (e.g., a surface farther away from the substrate 202) of the semiconductor structure 200b to a first dielectric layer 207 of the first deck 206a of the stack 201. A first isolation layer (not shown in FIG. 2B) is deposited on an inner wall of the isolating hole 210 and the bottom of the first isolation layer is etched with an etching process to expose the first dielectric layer 207 of the deck 206a of the stack 201. In some implementations, the first isolation layer can include a dielectric material different from the dielectric material of the dielectric layers 204a.

As shown in FIG. 2C, a semiconductor structure 200c is formed by removing a portion of the first dielectric layer 207 of the first deck 206a of the stack 201 to form a first connecting space 212 connected to the isolation hole 210, where the contact holes 208a, 208b, and 208c extend through the first connecting space along the Z direction. The first connecting space 212 can be filled with a first filler material. In some implementations, the first filler material is different from the dielectric material of the dielectric layers 204a and the dielectric material of the insulating layer 204b, and the filler material of the contact holes 208a, 208b, and 208c. For example, the insulating layers 204b can include silicon oxide, the dielectric layers 204a can include silicon nitride, the filler material of the contact holes 208a, 208b, and 208c can include polysilicon, and the first filler material can include carbon.

FIG. 2D illustrates a semiconductor structure 200d. The semiconductor structure 200d can be formed by removing the filler material in the contact holes 208b and 208c (e.g., by an etching process). In addition, a first dielectric spacer 216a between the contact hole 208b and the first filler material in the first connecting space 212, and a second dielectric spacer 216b between the contact hole 208c and the first filler material in the first connecting space 212 is formed by removing a portion of the filler material of the first connecting space 212 adjacent to the contact hole 208b and the contact hole 208c and depositing a dielectric material in the space. In some implementations, the dielectric spacers 216a and 216b can be formed by oxidizing a portion of the filler material of the first connecting space 212 through a thermal oxidation process. In some implementations, the first dielectric spacer 216a and the second dielectric spacer 216b can include a dielectric material similar to, or same as, the dielectric material of the insulating layer 204b.

FIG. 2E shows a semiconductor structure 200e, which are formed by filling the contact hole 208b and the contact hole 208c with a filler material.

FIG. 2F illustrates a semiconductor structure 200f. The semiconductor structure 200f can be formed by deepening the isolation hole 210 in the stack 201 by an etching process to create an isolation hole 220. The isolation hole 220 extends from a top (e.g., a surface farther away from the substrate 202) of the semiconductor structure 200f to a second dielectric layer 221 of the second deck 206b of the stack 201. A second isolation layer (not shown in FIG. 2F) is deposited on an inner wall of the isolating hole 220 and the bottom of the second isolation layer is etched with an etching process to expose the second dielectric layer 221 of the second deck 206b of the stack 201. In some implementations, the second isolation layer can include a dielectric material similar to, or same as, the dielectric material of the first isolation layer. In addition, a second connecting space 222 is formed by removing a portion of the second dielectric layer 221 of the second deck 206b of the stack 201, where the second connecting space 222 is connected to the isolation hole 220, where the contact holes 208b and 208c extend through the second connecting space 222 along the Z direction. The second connecting space 222 can be filled with the first filler material.

FIG. 2G illustrates a semiconductor structure 200g. The semiconductor structure 200g can be formed by removing the filler material in the contact holes 208c (e.g., by an etching process). In addition, a third dielectric spacer 226 between the contact hole 208c and the first filler material in the second connecting space 222 is formed by removing a portion of the filler material of the second connecting space 222 adjacent to the contact hole 208c and depositing a dielectric material in the space. In some implementations, the third dielectric spacers 226 can be formed by oxidizing a portion of the filler material of the second connecting space 222 through a thermal oxidation process. In some implementation, the third dielectric spacer 226 can include a dielectric material similar to, or same as, the dielectric material of the first dielectric spacer 216a and the second dielectric spacer 216b.

FIG. 2H shows a semiconductor structure 200h, which are formed by filling the contact the contact hole 208c with a filler material.

FIG. 2I illustrates a semiconductor structure 200i. The semiconductor structure 200i can be formed by deepening the isolation hole 220 in the stack 201 by an etching process to create an isolation hole 230. The isolation hole 230 extends from a top (e.g., a surface farther away from the substrate 202) of the semiconductor structure 200i to a third dielectric layer 231 of the third deck 206c of the stack 201. A third isolation layer (not shown in FIG. 2F) is deposited on an inner wall of the isolating hole 230 and the bottom of the second isolation layer is etched with an etching process to expose the third dielectric layer 231. In some implementations, the third isolation layer can include a dielectric material similar to, or same as, the dielectric material of the first isolation layer. In addition, a third connecting space 232 is formed by removing a portion of the third dielectric layer 231 of the third deck 206c of the stack 201, where the third connecting space 232 is connected to the isolation hole 230, where the contact hole 208c extends through the third connecting space 232 along the Z direction. The third connecting space 232 can be filled with the first filler material.

FIG. 2J shows a semiconductor structure 200j, which is formed by filling a filler material in the isolation hole 230.

FIG. 2K illustrates a semiconductor structure 200k. The semiconductor structure 200k includes tunnels 236. The tunnels 236 can be formed by filling a first etchant into a gate line slit (not shown in FIG. 2K) to remove a portion of each dielectric layers 204a of the stack 201. The gate line slit can be at a location similar to, or the same as, the location of the gate line structure 122 of FIGS. 1A-1B. The first etchant can be used to etch off the dielectric material of each dielectric layer 204a and may have little or no effect on the insulating layers 204b and the filler material of the connecting spaces 212, 222, and 232. The tunnels 236 expose the filler material in the first connecting space 212, the second connecting space 222, and the third connecting space 232. The tunnel separated the stack 201 into two regions along the Y direction. The first region includes the tunnels 236 in a stack 201a along the Z direction, and the second region includes the first connecting space 212, the second connecting space 222, the third connecting space 232 and the remaining portion of the dielectric layers 204a in the first deck 206a, the second deck 206b, and the third deck 206c of a stack 201b. Each deck in the stack 201b is connected to a corresponding deck in the stack 201a. For example, as shown in FIG. 2K, the first deck 206a in the stack 201b is connected to a first deck 205a of the stack 201a, the second deck 206b in the stack 201b is connected to a second deck 205b of the stack 201a, and the third deck 206c in the stack 201b is connected to a third deck 205c of the stack 201a.

FIG. 2L illustrates a semiconductor structure 200l. The semiconductor structure 200l includes recess spaces 238a, 238b, and 238c in the stack 201a. The recess spaces 238a, 238b, and 238c are formed by filling a second etchant into the gate line slit to remove a portion of the filler material in the first connecting space 212, the second connecting space 222, and the third connecting space 232. The second etchant can be used to etch off the filler material of the connecting spaces 212, 222, and 232 and may have little or no effect on the dielectric material of the dielectric layers 204a and the insulating layers 204b. The recess space 238a extends into the first deck 206a of the stack 201b and is connected to the first connecting space 212, the recess space 238b extends into the second deck 206b of the stack 201b and is connected to the second connecting space 222, and the recess space 238c extends into the third deck 206c of the stack 201b and is connected to the third connecting space 232 along the Y direction.

FIG. 2M illustrates a semiconductor structure 200m including conductive layers 240 in the stack 201a. The conductive layers 240 are formed by depositing liner layers 243 in the tunnel 236 and filling the remaining portion of the tunnel 236 with a conductive material surrounded by a conductive adhesion material. The liner layer 243 can include a high-K dielectric material (e.g., Al₂O₃). In some examples, the conductive layers 240 include a metallic material (e.g., W) and an adhesive material (e.g., TiN), and the adhesive material can be deposited between the metallic material and the high-K dielectric material. The semiconductor structure 200m also includes a first conductive layer 242a in the first deck 205a of the stack 201a, a second conductive layer 242b in the second deck 205b of the stack 201a, and a third conductive layer 242c in the third deck 205c of the stack 201a. The first conductive layer 242a, the second conductive layer 242b, and the third conductive layer 242c are formed by depositing liner layers 244 in the recess space 238a, 238b, and 238c, respectively, and filling the remaining portion of the recess space 238a, 238b, and 238c with a conductive material surrounded by a conductive adhesion material. In some implementations, an end 241a of the first conductive layer 242a, an end 241b of the second conductive layer 242b, and an end 241c of the third conductive layer 242c is closer to the contact hole 208a than an end 241d of the conductive layer 240. The liner layers 244 can include a high-K material similar to, or same as, the high-K material of the liner layers 243. The first conductive layer 242a, the second conductive layer 242b, and the third conductive layers 242c can include a metallic material and an adhesive material similar to, or same as, the metallic material and an adhesive material of the conductive layers 240.

FIG. 2N illustrate a semiconductor structure 200n. The semiconductor structure 200n can be formed by removing the filler material in the isolation hole 230. The filler material in the first connecting space 212, the second connecting space 222, and the third connecting space 232 of the stack 201b is removed by filling an etching solution through the isolation hole 230 creating connecting spaces. A portion of the liner layers 244 connected to the first connecting space 212, the second connecting space 222, and the third connecting space 232 is etched to create an opening along the Y direction. A first connecting layer 248a, a second connecting layer 248b, and a third connecting layer 248c in the stack 201b is formed by filling a conductive material in the connecting spaces. The first connecting layer 248a of the first deck 206a of the stack 201b is connected to the first conductive layer of the first deck 205a of the stack 201a, the second connecting layer 248b of the second deck 206b of the stack 201b is connected to the second conductive layer of the second deck 205b of the stack 201a, and the third connecting layer 248c of the third deck 206c of the stack 201b is connected to the third conductive layer of the third deck 205c of the stack 201a. The conductive material can include any suitable conducting material, such as W, Co, Cu, Al, TiN, polysilicon, doped silicon, silicides, or any combination thereof. In some implementations, the conductive material includes at least one of a metallic material, polysilicon, or TiN. In some other implementation, the conductive material is surrounded by an adhesion material.

FIG. 2O illustrates a semiconductor structure 200o including an isolating structure 254 in the stack 201b. The isolating structure 254 is formed by depositing a structural support material (e.g., silicon) with a dielectric (e.g., silicon oxide) layer in the isolation space 246. In some implementations, the isolating structure 254 is filled with a dielectric material such as Silicon oxide. The semiconductor structure 200o can includes a first contact structure 252a, a second contact structure 252b, and a third contact structure 252c. The first contact structure 252a, the second contact structure 252b, and the third contact structure 252c is formed by replacing the filling semiconductor material inside the contact hole 208a, 208b, and 208c with a conductive material through an etching and depositing process. The conductive material can include any suitable conducting material, such as W, Co, Cu, Al, TiN, polysilicon, doped silicon, silicides, or any combination thereof.

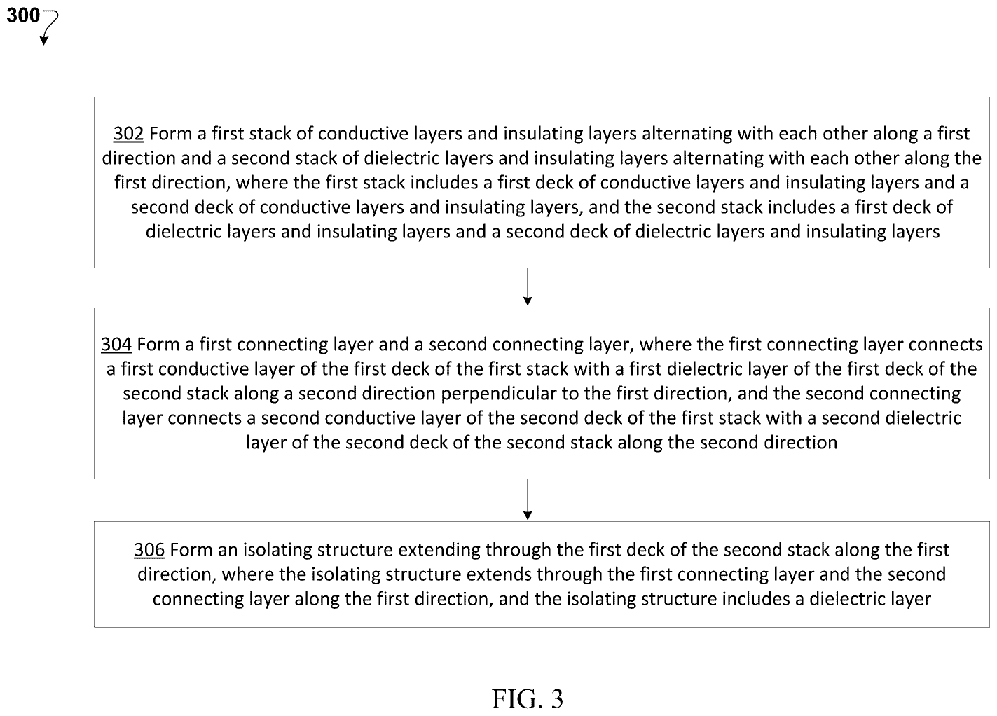

FIG. 3 illustrates a flow chart of an example process 300. The process 300 can be performed to form a semiconductor device (e.g., the semiconductor device 100 and the semiconductor device 100-2 illustrated by FIGS. 1A-1C). The process 300 can be described in view of FIGS. 2A-2O. The process 300 can include one or more steps of the fabrication process of forming the semiconductor structures in FIGS. 2A-2O. It is understood that the operations shown in process 300 are not exhaustive and that other operations can be performed as well before, after, or between any of the illustrated operations. Further, some of the operations may be performed simultaneously, or in a different order than shown in FIG. 3.

At operation 302, a first stack (e.g., the stack 201a of FIG. 2M) of conductive layers (e.g., the conductive layers 240 of FIG. 2M) and insulating layers (e.g., the insulating layers 204b of FIG. 2M) of a first semiconductor structure (e.g., the semiconductor structures 200m-200o of FIGS. 2M-2O) is formed. The first stack of conductive layers and insulating layers alternate with each other along a first direction (e.g., the Z direction). The first stack includes a first deck (e.g., the first deck 205a of the stack 201a of FIG. 2M) of conductive layers and insulating layers and a second deck (e.g., the second deck 205b of the stack 201a of FIG. 2M) of conductive layers and insulating layers stacked on top of the first deck of the first stack along the first direction. A second stack (e.g., the stack 201b of FIG. 2M) of dielectric layers (e.g., the dielectric layers 204a of FIG. 2M) and insulating layers (e.g., the insulating layers 204b of FIG. 2M) of the first semiconductor structure is formed. The second stack of dielectric layers and insulating layers alternate with each other along the first direction. The second stack includes a first deck (e.g., the first deck 206a of the stack 201b of FIG. 2M) of dielectric layers and insulating layers and a second deck (e.g., the second deck 206b of the stack 201b of FIG. 2M) of dielectric layers and insulating layers stacked on top of the first deck of the first stack along the first direction.

At operation 304, a first connecting layer (e.g., the first connecting layer 248a of FIG. 2N) and a second connecting layer (e.g., the second connecting layer 248b of FIG. 2N) of the first semiconductor structure is formed. The first connecting layer is connected to a first conductive layer (e.g., the first conductive layer 242a of FIG. 2N) of the first deck of the first stack and a first dielectric layers (e.g., the first dielectric layer 207 of FIG. 2N) of the first deck of the second stack along a second direction (e.g., the Y direction) perpendicular to the first direction. The second connecting layer is connected to a second conductive layer (e.g., the second conductive layer 242b of FIG. 2N) of the second deck of the first stack and a second dielectric layers (e.g., the second dielectric layer 221 of FIG. 2N) of the second deck of the second stack along the second direction.

At operation 306, an isolating structure (e.g., the isolating structure 254 of FIG. 2O) of the first semiconductor structure is formed. The isolating structure extends through the first deck, the first connecting layer, and the second connecting layer of the second stack along the first direction. The isolating structure includes a dielectric layer.

In some implementations, the first stack of the semiconductor structure further includes a third deck (e.g., the third deck 205c of the stack 201a of FIG. 2M) of conductive layers and insulating layers. The second stack of the semiconductor structure further includes a third deck (e.g., the third deck 206c of the stack 201b of FIG. 2M) of dielectric layers and insulating layers. The isolating structure of the first semiconductor structure extends through the first deck and the second deck of the second stack along the first direction and extends through at least a part of the third deck of the second stack along the first direction. The process of 300 includes forming a third connecting layer (e.g., the third connecting layer 248c of FIG. 2N) of the first semiconductor structure. The third connecting layer is connected to a third conductive layer (e.g., the third conductive layer 242c of FIG. 2N) of the third deck of the first stack and a third dielectric layers (e.g., the third dielectric layer 231 of FIG. 2N) of the third deck of the second stack along the second direction. The process of 300 further includes forming a first contact structure (e.g., the first contact structure 252a of FIG. 2O) of the first semiconductor structure. The first contact structure extends through the first deck of the second stack along the first direction. The first contact structure extends through and is connected with the first connecting layer. The process of 300 further includes forming a second contact structure (e.g., the second contact structure 252b of FIG. 2O) of the first semiconductor structure. The second contact structure extends through the first deck and the second deck of the second stack along the first direction. The second contact structure extends through the first connecting layer and the second connecting layer and is connected with the second connecting layer, and the second contact structure is isolated from the first connecting layer by a dielectric spacer (e.g., the first dielectric spacer 216a of FIG. 2N). The process of 300 further includes forming a third contact structure (e.g., the third contact structure 252c of FIG. 2O) of the first semiconductor structure. The third contact structure extends through the first deck, the second deck, and the third deck of the second stack along the first direction. The third contact structure extends through the first connecting layer, the second connecting layer, and the third connecting layer, the third contact structure is connected with the third connecting layer, and the third contact structure is isolated from the first connecting layer and the second connecting layer by dielectric spacers (e.g., the dielectric spacers 216b, 226 of FIG. 2N).

In some implementations, the process 300 includes forming a third stack (e.g., the stack 201 of FIG. 2A) of dielectric layers (e.g., the dielectric layers 204a of FIG. 2A) and insulating layers (e.g., the insulating layers 204b of FIG. 2A) along the first direction of a second semiconductor structure (e.g., the semiconductor structures 200a-200j of FIGS. 2A-2J), before forming the first stack and the second stack. The third stack of dielectric layers and insulating layers alternate with each other along the first direction. The third stack includes a first deck (e.g., the first deck 206a of the stack 201 of FIG. 2A) of dielectric layers and insulating layers, a second deck (e.g., the second deck 206b of the stack 201 of FIG. 2A) of dielectric layers and insulating layers, and a third deck (e.g., the third deck 206c of the stack 201 of FIG. 2A) of dielectric layers and insulating layers. The process 300 further includes forming the first stack and the second stack by replacing portions of the dielectric layers in the third stack by conductive layers. The process 300 further includes forming the first stack using the conductive layers and the insulating layers in the third stack between the conductive layers. The process 300 further includes forming the second stack using remaining portions of the dielectric layers in the third stack and the insulating layers between the remaining portions of the dielectric layers in the third stack.

In some implementations, the process 300 includes forming a first contact hole (e.g., the contact hole 208a of FIG. 2A), a second contact hole (e.g., the contact hole 208b of FIG. 2A), and a third contact hole (e.g., the contact hole 208c of FIG. 2A) extending along the first direction of the second semiconductor structure. The first contact hole extends through the first deck of the third stack, the second contact hole extends through the second deck of the third stack, and the third contact hole extends through the third deck of the third stack. The process 300 further includes forming an isolating hole (e.g., the isolation hole 210 of FIG. 2B) extending along the first direction. The isolating hole extends into the first deck of the third stack to expose a first dielectric layer (e.g., the first dielectric layer 207 of FIG. 2B) of the first deck of the third stack. The process 300 further includes depositing a dielectric layer on an inner wall of the isolating hole and removing a portion of the first dielectric layer of the first deck of the third stack to form a first connecting space (e.g., the first connecting space 212 of FIG. 2C) connected to the isolating hole. The first contact hole, the second contact hole, and the third contact hole extend through the first connecting space along the first direction. The process 300 further includes filling a filler material into the first connecting space and forming a first dielectric spacer (e.g., the first dielectric spacer 216a of FIG. 2D) between the second contact hole and the filler material in the first connecting space and a second dielectric spacer (e.g., the second dielectric spacer 216b of FIG. 2D) between the third contact hole and the filler material in the first connecting space. The process 300 further includes deepening the isolating hole along the first direction (e.g., the isolation hole 220 of FIG. 2F). The isolating hole extends into the second deck of the third stack to expose a second dielectric layer (e.g., the second dielectric layer 221 of FIG. 2F) of the second deck of the third stack. The process 300 further includes removing a portion of the second dielectric layer of the second deck of the third stack to form a second connecting space (e.g., the second connecting space 222 of FIG. 2H) connected to the isolating hole. The second contact hole and the third contact hole extend through the second connecting space along the first direction. The process 300 further includes filling the filler material into the second connecting space and forming a third dielectric spacer (e.g., the third dielectric spacer 226 of FIG. 2G) between the third contact hole and the filler material in the second connecting space. The process 300 further includes deepening the isolating hole along the first direction (e.g., the isolation hole 230 of FIG. 2I). The isolating hole extends into the third deck of the third stack to expose a third dielectric layer of the third deck of the third stack. The process 300 further includes removing a portion of the third dielectric layer (e.g., the third dielectric layer 231 of FIG. 2I) of the third deck of the third stack to form a third connecting space (e.g., the third connecting space 232 of FIG. 2I) connected to the isolating hole. The third contact hole extend through the third connecting space along the first direction. The process 300 further includes filling the filler material into the third connecting space and filling a sacrificial material into the isolating hole (e.g., the isolation hole 234 of FIG. 2J).

In some implementations, the process 300 includes forming a gate line slit (not shown in FIGS. 2A-2O) in the first semiconductor structure. The gate line slit extends through the third stack along the first direction. The process 300 further includes forming tunnels (e.g., the tunnels 236 of FIG. 2K) between the insulating layers in the third stack by filling an etchant into the gate line slit to remove a portion of each dielectric layer of the third stack. The tunnels expose the filler material in the first connecting space, the second connecting space, and the third connecting space, the first dielectric layer of the first deck of the second stack includes a remaining portion of the first dielectric layer of the first deck of the third stack, the second dielectric layer of the second deck of the second stack includes a remaining portion of the second dielectric layer of the second deck of the third stack, and the third dielectric layer of the third deck of the second stack includes a remaining portion of the third dielectric layer of the third deck of the third stack. The process 300 further includes forming a first recess (e.g., the recess space 238a of FIG. 2L), a second recess (e.g., the recess space 238b of FIG. 2L), a third recess (e.g., the recess space 238c of FIG. 2L) by removing a portion of the filler material in the first connecting space, the second connecting space, and the third connecting space, respectively. The process 300 further includes forming the conductive layers between the insulating layers in the third stack by depositing at least a conductive material in the tunnels, the first recess, the second recess, and the third recess.

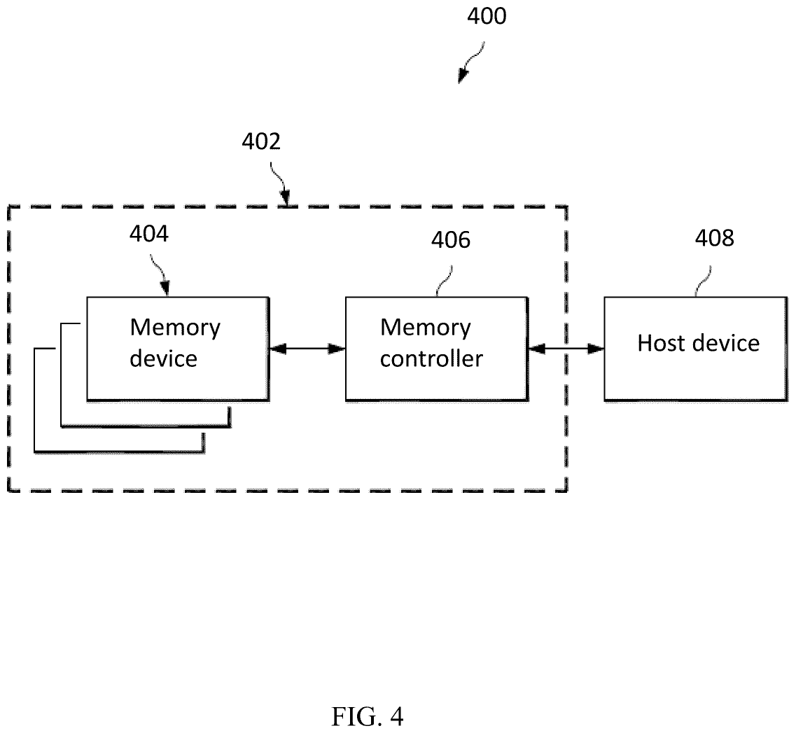

FIG. 4 illustrates a block diagram of an example system 400. The system 400 can have one or more semiconductor devices (e.g., memory devices), according to one or more implementations of the present disclosure. The system 400 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage. As shown in FIG. 4, the system 400 can include a host device 408 and a memory system 402 having one or more memory devices 404 and a memory controller 406. Host device 408 can include a processor of an electronic device, such as a central processing unit (CPU), or a system-on-chip (SoC), such as an application processor (AP). Host device 408 can be configured to send or receive data to or from the one or more memory devices 404.

A memory device 404 can be any memory device disclosed in the present disclosure, such as a memory device (e.g., a NAND Flash memory) as shown in FIGS. 1A-1C. Memory controller 406 (a.k.a., a controller circuit) is coupled to memory device 404 and host device 408. Consistent with implementations of the present disclosure, memory device 404 can include a plurality of conductive interconnections through a cover layer that are in contact with conductive pads in a conductive pad layer, and memory controller 406 can be coupled to memory device 404 through at least one of the plurality of conductive interconnections. Memory controller 406 is configured to control memory device 404. For example, memory controller 406 may be configured to operate a plurality of channel structures via word lines. Memory controller 406 can manage data stored in memory device 404 and communicate with host device 408.

In some implementations, memory controller 406 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 406 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 406 can be configured to control operations of memory device 404, such as read, erase, and program (or write) operations. Memory controller 406 can also be configured to manage various functions with respect to the data stored or to be stored in memory device 404 including, but not limited to bad-block management, garbage collection, logical-to-physical address conversion, wear leveling, etc. In some implementations, memory controller 406 is further configured to process error correction codes (ECCs) with respect to the data read from or written to memory device 404. Any other suitable functions may be performed by memory controller 406 as well, for example, formatting memory device 404.

Memory controller 406 can communicate with an external device (e.g., host device 408) according to a particular communication protocol. For example, memory controller 406 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 406 and one or more memory devices 404 can be integrated into various types of storage devices, for example, be included in the same package, such as a universal Flash storage (UFS) package or an eMMC package. That is, memory system 402 can be implemented and packaged into different types of end electronic products. In one example as shown in FIG. 4, memory controller 406 and a single memory device 404 may be integrated into a memory card 402. Memory card 402 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first stack of conductive layers and insulating layers alternating with each other along a first direction, wherein the first stack comprises a first deck of conductive layers and insulating layers and a second deck of conductive layers and insulating layers;
a second stack of dielectric layers and insulating layers alternating with each other along the first direction, wherein the second stack comprises a first deck of dielectric layers and insulating layers and a second deck of dielectric layers and insulating layers;
a first connecting layer connecting a first conductive layer of the first deck of the first stack with a first dielectric layer of the first deck of the second stack along a second direction perpendicular to the first direction;
a second connecting layer connecting a second conductive layer of the second deck of the first stack with a second dielectric layer of the second deck of the second stack along the second direction; and
an isolating structure extending through the first deck of the second stack along the first direction, wherein the isolating structure extends through the first connecting layer and the second connecting layer along the first direction, and the isolating structure comprises a dielectric layer.

2. The semiconductor device of claim 1, further comprising:
a first contact structure extending through the first deck of the second stack along the first direction, wherein the first contact structure extends through and is connected with the first connecting layer; and
a second contact structure extending through the first deck and the second deck of the second stack along the first direction, wherein the second contact structure extends through the first connecting layer and the second connecting layer and is connected with the second connecting layer, and the second contact structure is isolated from the first connecting layer by a dielectric spacer.

3. The semiconductor device of claim 2, wherein:
the first stack further comprises a third deck of conductive layers and insulating layers;
the second stack further comprises a third deck of dielectric layers and insulating layers;
a third connecting layer connects a third conductive layer of the third deck of the first stack with a third dielectric layer of the third deck of the second stack along the second direction;
a third contact structure extends through the first deck, the second deck, and the third deck of the second stack along the first direction, wherein the third contact structure extends through the first connecting layer, the second connecting layer, and the third connecting layer, the third contact structure is connected with the third connecting layer, and the third contact structure is isolated from the first connecting layer and the second connecting layer by dielectric spacers; and
the isolating structure extends through the first deck and the second deck of the second stack along the first direction and extends through at least a part of the third deck of the second stack along the first direction, wherein the isolating structure extends through the first connecting layer, the second connecting layer, and the third connecting layer along the first direction.

4. The semiconductor device of claim 1, wherein the first conductive layer of the first deck of the first stack and the second conductive layer of the second deck of the first stack extend into the second stack along the second direction.

5. The semiconductor device of claim 3, further comprising:
a gate line structure extending through the first stack along the first direction; and
channel structures extending through the first stack along the first direction.

6. The semiconductor device of claim 1, wherein the isolating structure further comprises a filling layer surrounded by the dielectric layer of the isolating structure.

7. The semiconductor device of claim 3, wherein the first contact structure does not extend into the second deck of the second stack, and the second contact structure does not extend into the third deck of the second stack.

8. The semiconductor device of claim 5, wherein a bottom end of the third contact structure and a bottom end of a channel structure of the channel structures are at a same position along the first direction.

9. A semiconductor device, comprising:
a first stack of conductive layers and insulating layers alternating with each other along a first direction, wherein the first stack comprises a first deck of conductive layers and insulating layers and a second deck of conductive layers and insulating layers;
a second stack of dielectric layers and insulating layers alternating with each other along the first direction, wherein the second stack comprises a first deck of dielectric layers and insulating layers and a second deck of dielectric layers and insulating layers;
a first connecting layer connecting a first conductive layer of the first deck of the first stack with a first dielectric layer of the first deck of the second stack along a second direction perpendicular to the first direction;
a second connecting layer connecting a second conductive layer of the second deck of the first stack with a second dielectric layer of the second deck of the second stack along the second direction;
a first contact structure extending through the first deck of the second stack along the first direction, wherein the first contact structure extends through and is connected with the first connecting layer; and
a second contact structure extending through the first deck and the second deck of the second stack along the first direction, wherein the second contact structure extends through the first connecting layer and the second connecting layer and is connected with the second connecting layer, and the second contact structure is isolated from the first connecting layer by a dielectric spacer.

10. The semiconductor device of claim 9, further comprising:
an isolating structure extending through the first deck of the second stack along the first direction, wherein the isolating structure extends through the first connecting layer and the second connecting layer along the first direction, and the isolating structure comprises a dielectric layer.

11. The semiconductor device of claim 10, wherein:
the first stack further comprises a third deck of conductive layers and insulating layers;
the second stack further comprises a third deck of dielectric layers and insulating layers;
a third connecting layer connects a third conductive layer of the third deck of the first stack with a third dielectric layer of the third deck of the second stack along the second direction;
a third contact structure extends through the first deck, the second deck, and the third deck of the second stack along the first direction, wherein the third contact structure extends through the first connecting layer, the second connecting layer, and the third connecting layer, the third contact structure is connected with the third connecting layer, and the third contact structure is isolated from the first connecting layer and the second connecting layer by dielectric spacers; and
the isolating structure extends through the first deck and the second deck of the second stack along the first direction and extends through at least a part of the third deck of the second stack along the first direction, wherein the isolating structure extends through the first connecting layer, the second connecting layer, and the third connecting layer along the first direction.

12. The semiconductor device of claim 9, wherein the first conductive layer of the first deck of the first stack and the second conductive layer of the second deck of the first stack extend into the second stack along the second direction.

13. The semiconductor device of claim 11, further comprising:
a gate line structure extending through the first stack along the first direction; and
channel structures extending through the first stack along the first direction.

14. The semiconductor device of claim 10, wherein the isolating structure further comprises a filling layer surrounded by the dielectric layer.

15. A method, comprising:
forming a first stack of conductive layers and insulating layers alternating with each other along a first direction and a second stack of dielectric layers and insulating layers alternating with each other along the first direction, wherein the first stack comprises a first deck of conductive layers and insulating layers and a second deck of conductive layers and insulating layers, and the second stack comprises a first deck of dielectric layers and insulating layers and a second deck of dielectric layers and insulating layers;
forming a first connecting layer and a second connecting layer, wherein the first connecting layer connects a first conductive layer of the first deck of the first stack with a first dielectric layer of the first deck of the second stack along a second direction perpendicular to the first direction, and the second connecting layer connects a second conductive layer of the second deck of the first stack with a second dielectric layer of the second deck of the second stack along the second direction; and
forming an isolating structure extending through the first deck of the second stack along the first direction, wherein the isolating structure extends through the first connecting layer and the second connecting layer along the first direction, and the isolating structure comprises a dielectric layer.

16. The method of claim 15, wherein:
the first stack further comprises a third deck of conductive layers and insulating layers;
the second stack further comprises a third deck of dielectric layers and insulating layers;
the isolating structure extends through the first deck and the second deck of the second stack along the first direction and extends through at least a part of the third deck of the second stack along the first direction; and
the method further comprises:
forming a third connecting layer connecting a third conductive layer of the third deck of the first stack with a third dielectric layer of the third deck of the second stack along the second direction;
forming a first contact structure extending through the first deck of the second stack along the first direction, wherein the first contact structure extends through and is connected with the first connecting layer;
forming a second contact structure extending through the first deck and the second deck of the second stack along the first direction, wherein the second contact structure extends through the first connecting layer and the second connecting layer and is connected with the second connecting layer, and the second contact structure is isolated from the first connecting layer by a dielectric spacer; and
forming a third contact structure extending through the first deck, the second deck, and the third deck of the second stack along the first direction, wherein the third contact structure extends through the first connecting layer, the second connecting layer, and the third connecting layer, the third contact structure is connected with the third connecting layer, and the third contact structure is isolated from the first connecting layer and the second connecting layer by dielectric spacers.

17. The method of claim 16, further comprising:
before forming the first stack and the second stack, forming a third stack of dielectric layers and insulating layers alternating with each other along the first direction, wherein the third stack comprises a first deck of dielectric layers and insulating layers, a second deck of dielectric layers and insulating layers, and a third deck of dielectric layers and insulating layers, and wherein:
forming the first stack and the second stack comprises:
replacing portions of the dielectric layers in the third stack by conductive layers;
forming the first stack using the conductive layers and the insulating layers in the third stack between the conductive layers; and
forming the second stack using remaining portions of the dielectric layers in the third stack and the insulating layers between the remaining portions of the dielectric layers in the third stack.

18. The method of claim 17, wherein:
forming the first contact structure, the second contact structure, and the third contact structure comprises forming a first contact hole, a second contact hole, and a third contact hole extending along the first direction, wherein the first contact hole extends through the first deck of the third stack, the second contact hole extends through the second deck of the third stack, and the third contact hole extends through the third deck of the third stack; and
forming the isolating structure comprises forming an isolating hole extending along the first direction, wherein the isolating hole extends into the first deck of the third stack to expose a first dielectric layer of the first deck of the third stack, and wherein the method further comprises:
depositing a dielectric layer on an inner wall of the isolating hole;
removing a portion of a first dielectric layer of the first deck of the third stack to form a first connecting space connected to the isolating hole, wherein the first contact hole, the second contact hole, and the third contact hole extend through the first connecting space along the first direction;
filling a filler material into the first connecting space;
forming a first dielectric spacer between the second contact hole and the filler material in the first connecting space and a second dielectric spacer between the third contact hole and the filler material in the first connecting space;
deepening the isolating hole along the first direction, wherein the isolating hole extends into the second deck of the third stack to expose a second dielectric layer of the second deck of the third stack;
removing a portion of the second dielectric layer of the second deck of the third stack to form a second connecting space connected to the isolating hole, wherein the second contact hole and the third contact hole extend through the second connecting space along the first direction;
filling the filler material into the second connecting space;
forming a third dielectric spacer between the third contact hole and the filler material in the second connecting space;
deepening the isolating hole along the first direction, wherein the isolating hole extends into the third deck of the third stack to expose a third dielectric layer of the third deck of the third stack;
removing a portion of the third dielectric layer of the third deck of the third stack to form a third connecting space connected to the isolating hole, wherein the third contact hole extend through the third connecting space along the first direction;
filling the filler material into the third connecting space; and
filling a sacrificial material into the isolating hole.

19. The method of claim 18, wherein the conductive layers are formed by:
forming a gate line slit extending through the third stack along the first direction;
forming tunnels between the insulating layers in the third stack by filling an etchant into the gate line slit to remove a portion of each dielectric layer of the third stack, wherein the tunnels expose the filler material in the first connecting space, the second connecting space, and the third connecting space, the first dielectric layer of the first deck of the second stack comprises a remaining portion of the first dielectric layer of the first deck of the third stack, the second dielectric layer of the second deck of the second stack comprises a remaining portion of the second dielectric layer of the second deck of the third stack, and the third dielectric layer of the third deck of the second stack comprises a remaining portion of the third dielectric layer of the third deck of the third stack;
forming a first recess, a second recess, a third recess by removing a portion of the filler material in the first connecting space, the second connecting space, and the third connecting space, respectively; and
forming the conductive layers between the insulating layers in the third stack by depositing at least a conductive material in the tunnels, the first recess, the second recess, and the third recess.

20. The method of claim 19, further comprising:
removing the sacrificial material in the isolating hole; and
removing the filler material in the first connecting space, the second connecting space, and the third connecting space,
and wherein:
forming the first connecting layer, the second connecting layer, and the third connecting layer comprises depositing at least a conductive material into the first connecting space, the second connecting space, and the third connecting space respectively through the isolating hole;
forming the isolating structure further comprises filling a dielectric material into the isolating hole; and
forming the first contact structure, the second contact structure, and the third contact structure further comprises filling at least a conductive material into the first contact hole, the second contact hole, and the third contact hole.
